(19) United States
(12) Patent Application Publication
(10) Pub. No.: US 2013/0292747 A1
(43) Pub. Date: Nov. 7, 2013

(54) SEMICONDUCTOR DEVICE AND METHOD FOR FABRICATING THE SAME

(71) Applicant: Sangwoo KANG, Yongin-si (KR)

(72) Inventor: Sangwoo KANG, Yongin-si (KR)

(73) Assignee: SK hynix Inc., Icheon (KR)

(21) Appl. No.: 13/607,605

(22) Filed: Sep. 7, 2012

(30) Foreign Application Priority Data
May 2, 2012 (KR) 10-2012-0046319

(51) Int. Cl. H01L 29/78; H01L 21/28

(52) U.S. Cl. 257/288; 438/592; 257/E29.255; 257/E21.19

(57) ABSTRACT

A semiconductor memory device and a method for fabricating the sane are disclosed. In the semiconductor device, an insulation film of a drain region is formed to have a thick thickness in a local region such that it improves Hot Carrier Degradation (HCD) characteristics. The semiconductor device includes a first insulation film formed over a semiconductor substrate, a gate formed over the first insulation film, and a second insulation film located at a specific region between the first insulation film and the gate.

### CROSS-REFERENCE TO RELATED APPLICATION

The priority of Korean patent application No. 10-2012-0046319 filed on 2 May 2012, the disclosure of which is hereby incorporated in its entirety by reference, is claimed.

### BACKGROUND OF THE INVENTION

Embodiments of the present invention relate to a semiconductor device and a method for fabricating the same, and more specifically to a semiconductor device and a method for fabricating the same, in which an additional insulation film is formed between a drain region and a gate.

Generally, a metal-oxide semiconductor field effect transistor (MOSFET) element is configured to sequentially deposit a silicon oxide film and a polysilicon (poly-Si) layer over a semiconductor substrate including a drain region and a source region, resulting in formation of a gate structure.

Thereafter, ion doping is performed on the polysilicon film such that the polysilicon film is used as a gate. Although the polysilicon film is doped, semiconductor characteristics still remain in the doped polysilicon film. As a result, a depletion layer is formed at the entire interface between the polysilicon film and the silicon oxide film upon receiving a voltage.

The depletion layer has the same effect as increasing a thickness of the silicon oxide film would have, thus causing Drain Induced Barrier Lowering (DIBL) characteristics and the like, which deteriorate device performance.

In addition, if a sufficient amount of voltage is applied to a drain terminal of the MOSFET element, electrons or hole carriers of the MOSFET element cause lattice collision, resulting in formation of an electron-hole-pair. In this case, the carrier is referred to as a hot carrier. Hot carriers may destroy Si—H/Si—O bonding formed at an interface of the silicon oxide film. Also, the carrier may be trapped in an oxide film, causing a hot carrier degradation (HCD) effect by which a threshold voltage is increased and a current is reduced. Specifically, if pinch-off occurs, an electric field (Emax) exponentially increases, resulting in the occurrence of a large amount of hot carriers.

### BRIEF SUMMARY OF THE INVENTION

Various embodiments of the present invention are directed to providing a semiconductor device and a method for fabricating the same that substantially obviate one or more problems due to limitations or disadvantages of the related art.

Embodiments of the present invention relate to a semiconductor memory device and a method for fabricating the same so as to improve HCD characteristics.

In accordance with one embodiment of the present invention, a semiconductor device includes a first insulation film formed over a semiconductor substrate; a gate formed over the first insulation film; and a second insulation film located in a specific region between the first insulation film and the gate.

The second insulation film may is an air gap or a spacer material. The second insulation film may be located at a drain region.

The gate may be formed thicker at a second region adjacent to a source region than at a first region adjacent to a drain region.

The gate may include a first conductive layer formed over the first insulation film; and a second conductive layer formed over the first conductive layer.

The first conductive layer may be thinner than the second conductive layer. The first conductive layer may be formed of a material having a higher etch-selection-ratio than that of the second conductive layer. The first conductive layer may be formed of a polysilicon germanium (poly-SiGe) material, and the second conductive layer may be formed of a polysilicon (poly-Si) material. The first conductive layer may be formed to a thickness of 100 Å or less. The first insulation film may be a gate insulation film.

In accordance with another embodiment of the present invention, a semiconductor device includes a gate insulation film formed over a semiconductor substrate including a source region and a drain region; an air gap located in a region proximate to the drain region and provided over the gate insulating film; and a gate formed over the gate insulation film and the air gap.

The gate may include a first conductive layer formed at a lateral surface of the air gap formed over the gate insulation film; and a second conductive layer formed over the first conductive layer.

In accordance with another embodiment of the present invention, a method for fabricating a semiconductor device includes forming a gate insulation film over a semiconductor substrate; forming a first conductive layer over the gate insulation film; forming a second conductive layer over the first conductive layer; forming a gate structure by patterning the first conductive layer and the second conductive layer; and removing a portion of the first conductive layer by etching a sidewall of the first conductive layer to form a recess.

The method may further include forming a spacer at both sidewalls of the gate structure.

The forming of the spacer may further include filling the recess with a material forming the spacer.

The removing of a portion of the first conductive layer may include removing a portion of the first conductive layer of a drain region.

The removing of the portion of the first conductive layer includes removing the first conductive layer so that a width of the first conductive layer is shortened by ¼ or less.

In accordance with one embodiment of the present invention, a semiconductor device comprises a lower gate electrode with a first sidewall; an upper gate electrode with a second sidewall, wherein the first sidewall extends from the second sidewall and is recessed from the second sidewall.

The lower gate has a first width, wherein the upper gate has a second width, and wherein the first width is smaller than the second width.

The first and the second sidewalls are facing a drain region.

The device further comprises a gate spacer provided over the second sidewall, and an insulating pattern defined by the first and the second sidewalls and the gate spacer.

The insulating pattern is an air gap.

The insulating pattern is filled by the gate spacer to form an arm of the gate spacer that extends from the gate spacer to the recessed first sidewall.

In accordance with one embodiment of the present invention, a semiconductor device comprises a gate electrode with a recessed sidewall profile at a bottom portion.

In accordance with one embodiment of the present invention, a semiconductor device comprises

In accordance with another embodiment of the present invention, a method for fabricating a semiconductor device includes forming a lower gate electrode layer with a first sidewall over a semiconductor substrate; forming an upper gate electrode with a second sidewall over the lower gate electrode; and patterning the first sidewall of the lower gate electrode so that the lower gate electrode layer has a third sidewall that is recessed from the second sidewall.

The method further comprises providing a gate spacer over the second sidewall to form an air gap between the third sidewall and the gate spacer.

The method further comprises providing insulating material over the second and the third sidewalls to form a gate spacer, wherein the gate spacer has an arm extending to the second sidewall.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a cross-sectional view illustrating a semiconductor device according to an embodiment of the present invention.

FIGS. 2A to 2F are cross-sectional views illustrating a method for fabricating a semiconductor device according to embodiments of the present invention.

FIGS. 3a and 3b are an SEM photograph and its reproduced diagram showing recesses formed on a sidewall of a gate electrode of a semiconductor device according to embodiments of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. In the following description of the present invention, a detailed description of related known configurations or functions incorporated herein will be omitted if it would make the subject matter of the present invention unclear.

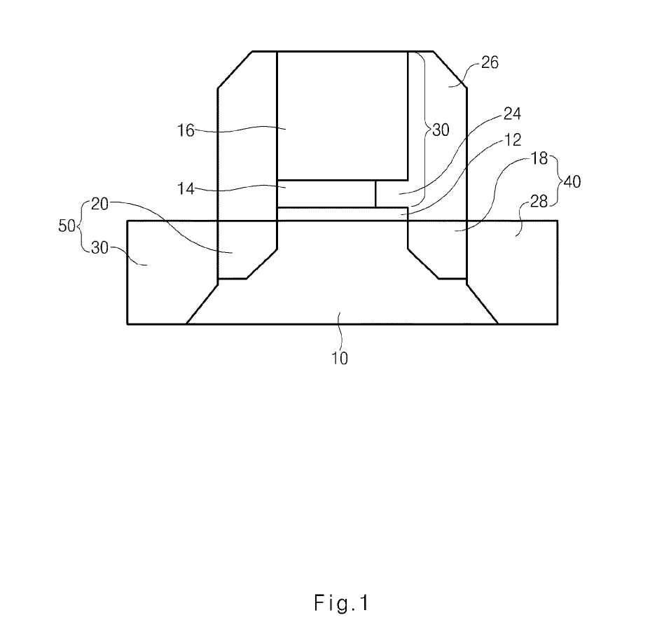

The semiconductor device and a method for fabricating the same according to embodiments of the present invention will hereinafter be described with reference to FIGS. 1 to 3b.

FIG. 1 is a cross-sectional view illustrating a semiconductor device according to an embodiment of the present invention.

Referring to FIG. 1, a semiconductor device according to an embodiment of the present invention includes a drain region 40 and a source region 50 at either side of a semiconductor substrate 10. A gate insulation film 12 and a gate electrode 30 are provided over the semiconductor substrate 10. Some parts of a sidewall of the gate electrode 30 facing the drain region 40 may be recessed so that an air gap or an insulation film 24 is formed between the gate electrode 30 and the drain region 40. A spacer 26 is formed at both sidewalls of the gate electrode 30.

In an embodiment, the gate electrode 30 is formed to have a hybrid structure in which a polysilicon germanium (poly-SiGe) layer 14 and a polysilicon (poly-Si) 16 are sequentially deposited over a gate insulation film 12. Although the gate electrode 30 according to an embodiment of the present invention is configured as a hybrid structure composed of the poly-SiGe layer 14 and the poly-Si layer 16, the gate electrode 30 may also be implemented as a single-structured gate electrode 30 formed of only the poly-SiGe layer.

The poly-Si layer 16 according to an embodiment of the present invention may be replaced with metal (for example, tungsten (W), titanium (Ti), titanium nitride (TiN), etc.) or polysilicon. The poly-SiGe layer 14 may be replaced with a material that has a higher etch selection ratio with respect to the poly-Si layer 16 and/or a higher conductivity than the poly-Si layer 16.

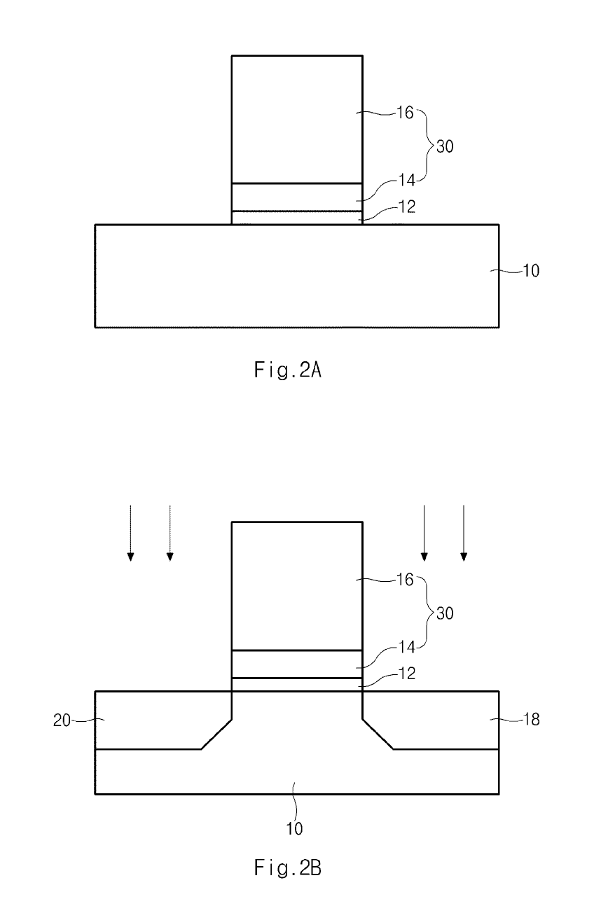

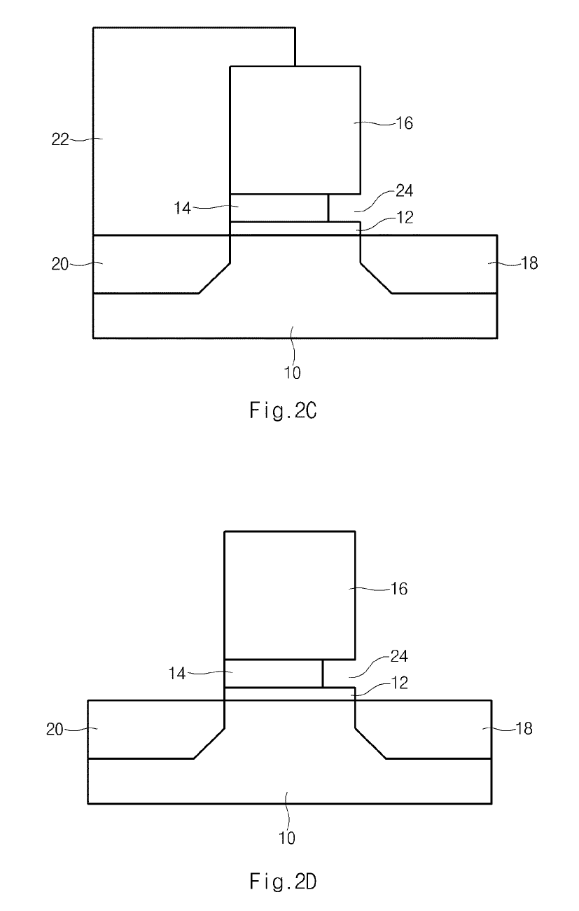

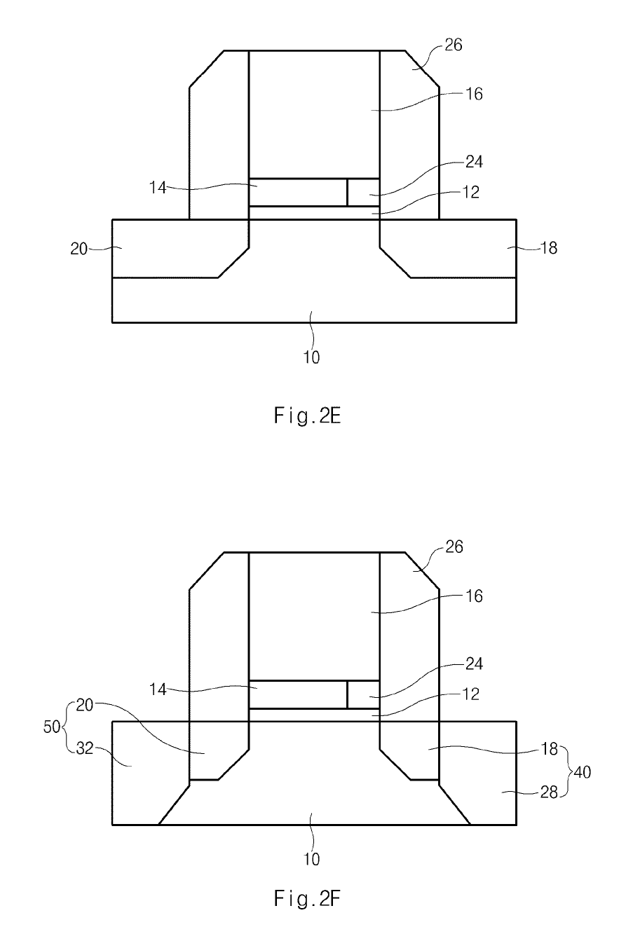

FIGS. 2A to 2F are cross-sectional views illustrating a method for fabricating a semiconductor device according to embodiments of the present invention.

Referring to FIG. 2A, the gate insulation film 12, the poly-SiGe layer 14, and the poly-Si layer 16 are sequentially deposited over the semiconductor substrate 10. Thereafter, a stack pattern of the gate insulation film 12 and the gate electrode 30 is formed over the semiconductor substrate through an etching process. Preferably, the gate insulation film 12 may be formed of a nitride material, a silicon oxide material, a high-K material such as HfO₂, HfSiON, etc.

In addition, the poly-SiGe layer 14 may be deposited to a thickness of 100 micrometers or less in such a manner that it can be selectively used in the range affecting actual polysilicon deposition characteristics. In order to guarantee the height of a gate stack, the poly-Si layer 16 may be formed to be thicker than the poly-SiGe layer 14. The poly-SiGe layer 14 may be replaced with a semiconductor or metal material that has a superior etch selection ratio with respect to the poly-Si layer 16 and superior depletion characteristics compared to the poly-Si layer 16.

Thereafter, as shown in FIG. 2B, dopants in use for forming a lightly doped drain (LDD) region and/or halo ions are implanted into the substrate 10 on both sides of the gate electrode 30, so that a first drain region 18 and a first source region 20 are formed, respectively.

Subsequently, as shown in FIG. 2C, a photoresist (PR) layer is formed over the first source region 20, and is patterned so that a sidewall of the gate electrode 30 of the first drain region 18 is exposed. Although FIG. 2C exemplarily shows that the photoresist layer 22 is formed not only over the first source region 20 but also over some parts of the gate electrode 30, it should be noted that the photoresist layer 22 may be formed to cover the entirety of an upper part of the gate electrode 30 and the first source region 20, and may be formed in various shapes so long as a sidewall of the gate electrode 30 facing the first drain region 18 is exposed.

After the sidewall of the gate electrode 30 facing the first drain region 18 is exposed, the poly-SiGe layer 14 is selectively etched. In other words, the poly-Si layer 16 from among the gate electrode 30 remains intact, and only the poly-SiGe layer 14 is selectively etched to form a recess on the sidewall. Preferably, the poly-SiGe layer 14 may be etched by, for example, about ¼ or less of the width of the gate electrode 30.

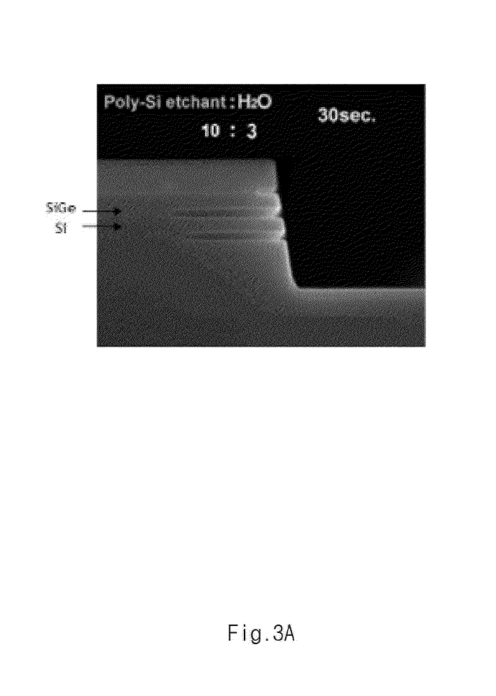

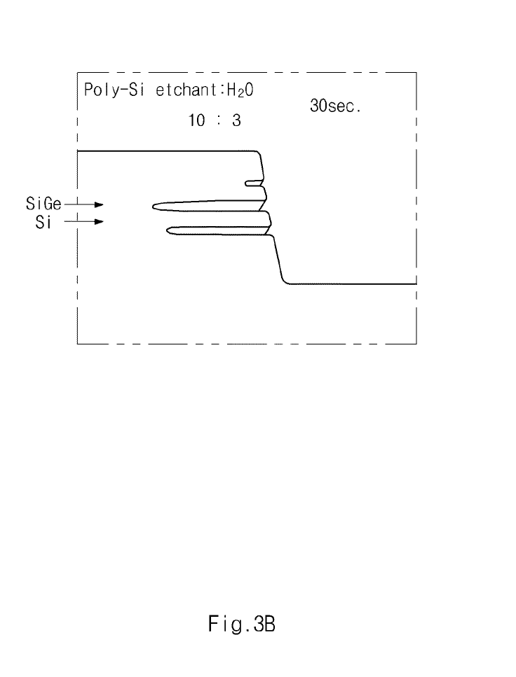

FIGS. 3a and 3b are an SEM photograph and its reproduced diagram showing the recesses on the sidewall facing the first drain region 18 according to an embodiment of the present invention. As can be seen from the SEM photograph of FIGS. 3a and 3b, an etch ratio of the poly-SiGe layer is different from that of the poly-Si layer, such that only the poly-SiGe layer is selectively etched.

After the sidewall of the gate electrode 30 is etched, the photoresist layer 22 is removed as shown in FIG. 2D.

Subsequently, as shown in FIG. 2E, spacers 26 are formed at both sidewalls of the gate electrode 30. For example, in an embodiment, if a material serving as the spacer 26 has superior step coverage, the material used as the spacer 26 may fill the recess and extend into the sidewall of the gate electrode 30. In contrast, in another embodiment, if the material serving as the spacer 26 has a poor step coverage property, the recess can be reduced to an air gap 24. Either of the above-mentioned two examples can be employed in accordance with the present invention. That is, the recess may remain empty to form the air gap or may be filled with an insulation material (spacer material) to form the spacer 26 with an arm extending into the sidewall of the gate electrode 30.

Thereafter, as shown in FIG. 2F, high-density impurity ions are implanted into the first drain region 18 and the first source region 20 using the spacer 26 as a mask, such that a second drain region 28 and a second source region 32 are formed. In an embodiment, the second drain region 28 may be deeper than the first drain region 18, and the second source region 32 may be deeper than the first source region 20.

Thus, as described above, in accordance with the embodiments of the present invention, some parts of the poly-SiGe layer 14 facing the drain region 40 are etched to form recesses so that the air gap 24 or the arm extending from the spacer 26 into the gate electrode 30 can be formed. As a result, Drain Induced Barrier Lowering (DIBL) phenomenon can be prevented even when a high operation voltage is applied to the semiconductor device. Thus, an electron-hole-pairing effect can be reduced, and destruction of Si—H/Si—O bonding at the channel interface can be prevented. Also, electron trapping at the channel interface can be reduced, thus preventing hot carrier degradation (HCD). In addition, gate induced drain leakage (GIDL) characteristics can be improved due to the air gap 24 or the arm extending from the spacer 26 into the gate electrode 30.

Furthermore, according to the semiconductor device of the present invention, dopant activation characteristics of the poly-SiGe layer are superior to those of the poly-Si layer, such that the polysilicon depletion effect can be improved.

As is apparent from the above description, a semiconductor device and a method for fabricating the same have the following effects.

First, a recess is formed at a gate sidewall facing a drain region using an etch-selection-ratio material (e.g., poly-SiGe) higher than that of a polysilicon (poly-Si) layer, such that an insulation film of the drain region is formed to be partially thicker, resulting in HCD improvement.

Second, dopant activation is more facilitated in the poly-SiGe layer than the poly-Si layer. Thus, the polysilicon depletion effect can be greatly improved.

Those skilled in the art will appreciate that the present invention may be carried out in other specific ways than those set forth herein without departing from the spirit and essential characteristics of the present invention. The above exemplary embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it is obvious to those skilled in the art that claims that are not explicitly cited in each other in the appended claims may be presented in combination as an exemplary embodiment of the present invention or included as a new claim by a subsequent amendment after the application is filed.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a first insulation film formed over a semiconductor substrate;
a gate formed over the first insulation film; and
a second insulation film located in a specific region between the first insulation film and the gate.

2. The semiconductor device according to claim 1, wherein the second insulation film is an air gap or a spacer material.

3. The semiconductor device according to claim 1, wherein the second insulation film is located in a drain region.

4. The semiconductor device according to claim 1, wherein the gate is formed thicker at a second region adjacent to a source region than at a first region adjacent to a drain region.

5. The semiconductor device according to claim 1, wherein the gate includes:
a first conductive layer formed over the first insulation film; and
a second conductive layer formed over the first conductive layer.

6. The semiconductor device according to claim 5, wherein the first conductive layer is thinner than the second conductive layer.

7. The semiconductor device according to claim 5, wherein the first conductive layer is formed of a material having an etch-selection-ratio higher than that of the second conductive layer.

8. The semiconductor device according to claim 5, wherein the first conductive layer is formed of a polysilicon germanium (poly-SiGe) material, and the second conductive layer is formed of a polysilicon (poly-Si) material.

9. The semiconductor device according to claim 5, wherein the first conductive layer is formed to have a thickness of 100 micrometers or less.

10. The semiconductor device according to claim 1, wherein the first insulation film is a gate insulation film.

11. A semiconductor device comprising:
a gate insulation film formed over a semiconductor substrate including a source region and a drain region;
an air gap located in a region proximate to the drain region and provided over the gate insulating film; and
a gate formed over the gate insulation film and the air gap.

12. The semiconductor device according to claim 11, wherein the gate includes:
a first conductive layer formed at a lateral surface of the air gap formed over the gate insulation film; and
a second conductive layer formed over the first conductive layer.

13. The semiconductor device according to claim 12, wherein the first conductive layer is formed of a material having an etch-selection-ratio higher than that of the second conductive layer.

14. The semiconductor device according to claim 12, wherein the first conductive layer is formed of a polysilicon germanium (poly-SiGe) material, and the second conductive layer is formed of a polysilicon (poly-Si) material.

15. A method for fabricating a semiconductor device comprising:
forming a gate insulation film over a semiconductor substrate;
forming a first conductive layer over the gate insulation film;
forming a second conductive layer over the first conductive layer;
forming a gate structure by patterning the first conductive layer and the second conductive layer; and
removing a portion of the first conductive layer by etching a sidewall of the first conductive layer to form a recess.

16. The method according to claim 15, further comprising forming a spacer at both sidewalls of the gate structure.

17. The method according to claim 16, wherein the forming of the spacer further includes: filling the recess with a material for forming the spacer.

18. The method according to claim 15, wherein the removing of a portion of the first conductive layer includes: removing a portion of the first conductive layer of a drain region.

19. The method according to claim 15, wherein the first conductive layer is formed of a material having an etch-selection-ratio higher than that of the second conductive layer.

20. The method according to claim 15, wherein the first conductive layer is formed of a polysilicon germanium (poly-SiGe) material, and the second conductive layer is formed of a polysilicon (poly-Si) material.

21. The method according to claim 15, wherein the removing of the portion of the first conductive layer includes removing the first conductive layer so that a width of the first conductive layer is shortened by ¼ or less.

22. A semiconductor device comprising:
a lower gate electrode with a first sidewall;
an upper gate electrode with a second sidewall,
wherein the first sidewall extends from the second sidewall and is recessed from the second sidewall.

23. The semiconductor device of claim 22,
wherein the lower gate electrode has a first width,
wherein the upper gate electrode has a second width, and
wherein the first width is smaller than the second width.

24. The semiconductor device of claim 22,
wherein the first and the second sidewalls are facing a drain region.

25. The semiconductor device of claim 22, the device further comprising:
a gate spacer provided over the second sidewall, and
an insulating pattern defined by the first and the second sidewalls and the gate spacer.

26. The semiconductor device of claim 25,
wherein the insulating pattern is an air gap.

27. The semiconductor device of claim 25,
wherein the insulating pattern is filled by the gate spacer to form an arm of the gate spacer that extends from the gate spacer to the recessed first sidewall.

28. A semiconductor device comprising:
a gate electrode with a recessed sidewall profile at a bottom portion.

29. A method for forming a semiconductor device comprising:
forming a lower gate electrode layer with a first sidewall over a semiconductor substrate;
forming an upper gate electrode with a second sidewall over the lower gate electrode; and
patterning the first sidewall of the lower gate electrode so that the lower gate electrode layer has a third sidewall that is recessed from the second sidewall.

30. The method of claim 29, the method further comprising:
providing a gate spacer over the second sidewall to form an air gap between the third sidewall and the gate spacer.

31. The method of claim 29, the method further comprising:
providing insulating material over the second and the third sidewalls to form a gate spacer,
wherein the gate spacer has an arm extending to the second sidewall.
